(19) United States
(12) Patent Application Publication
(10) Pub. No.: US 2026/0040704 A1
(43) Pub. Date: Feb. 5, 2026

(54) PHOTODETECTOR

(71) Applicant: SHARP KABUSHIKI KAISHA, Osaka (JP)

(72) Inventors: TADAYOSHI MIYAMOTO, Osaka (JP); Fumiki Nakano, Osaka (JP)

(21) Appl. No.: 19/283,668

(22) Filed: Jul. 29, 2025

(30) Foreign Application Priority Data
Aug. 2, 2024 (JP) 2024-128219

(51) Int. Cl. H10F 39/00; G01T 1/20; H10F 39/18

(52) U.S. Cl. CPC H10F 39/80377; G01T 1/2018; H10F 39/016; H10F 39/1898; H10F 39/8033

(57) ABSTRACT

A photodetector includes: a photodiode configured to convert light into an electric charge; and a TFT configured to detect the electric charge. The TFT includes a gate electrode, a source electrode, a drain electrode, and an oxide semiconductor film. The oxide semiconductor film includes a first region overlapping the source electrode in a plan view, a second region overlapping the drain electrode in the plan view, and a third region located between the first region and the second region, and overlapping only the gate electrode in the plan view. In the plan view, a width of the oxide semiconductor film in a second direction is smaller than widths of the source and drain electrodes, the second direction being perpendicular to a first direction and perpendicular to the oxide semiconductor film, the first direction being a direction passing through the individual first, second, and third regions in a shortest distance.

### CROSS-REFERENCE TO RELATED APPLICATIONS

The present application claims priority from Japanese Application JP2024-128219, the content of which is hereby incorporated by reference into this application.

### BACKGROUND

### Technical Field

The present disclosure relates to a photodetector including a photodiode and a thin-film transistor.

Flat-panel photodetectors in which photodiodes that convert light into electric charges, and thin-film transistors (TFTs) that function as switching elements are arranged in matrix have been widely used as image sensors, photosensors, and other things. Japanese Unexamined Patent Application Publication No. 2013-156119 discloses an example radiographic imaging device including such a photodetector.

Japanese Unexamined Patent Application Publication No. 2013-156119 discloses that a semiconductor film included in a TFT may be formed from an oxide semiconductor, such as indium gallium zinc oxide (InGaZnO) or zinc oxide (ZnO). Oxide semiconductors have lower leakage current than the other semiconductors.

However, the photodetector's TFTs sustain damage in the process of forming the photodiode after TFT formation. This unfortunately increases leakage current.

### SUMMARY

An object of one aspect of the present disclosure is to achieve a photodetector with reduced leakage current.

To solve the above problem, a photodetector according to one aspect of the present disclosure includes the following: a photodiode configured to convert light into an electric charge; and a thin-film transistor (TFT) configured to detect the electric charge. The TFT includes a gate electrode, a source electrode, a drain electrode, and an oxide semiconductor film striding between the source electrode and the drain electrode. The oxide semiconductor film includes a first region overlapping the source electrode in a plan view, a second region overlapping the drain electrode in the plan view, and a third region located between the first region and the second region, and overlapping only the gate electrode in the plan view. In the plan view, the width of the oxide semiconductor film in a second direction is smaller than the widths of the source and drain electrodes. The second direction is perpendicular to a first direction and perpendicular to the oxide semiconductor film. The first direction is a direction passing through the individual first, second, and third regions in the shortest distance.

The aspect of the present disclosure can achieve a photodetector with reduced leakage current.

### BRIEF DESCRIPTION OF THE DRAWINGS

FIG. 1 is a schematic cross-sectional view and plan view of a photodetector according to a first embodiment;

FIG. 2 is a schematic plan view of a TFT included in the photodetector according to the first embodiment;

FIG. 3 is a cross-sectional view of the schematic structure of a known photodetector;

FIG. 4 is a plan view of the schematic structures of TFTs;

FIG. 5 is a graph showing the relationship1 in the TFT between the thickness of a gate insulating film and the amount of variation of a threshold voltage;

FIG. 6 is graphs showing the relationship between gate voltage and drain current in the TFTs;

FIG. 7 is graphs showing changes caused by X-ray irradiation, in the relationship between the gate voltage and drain current in the TFTs;

FIG. 8 is a schematic plan view of an example TFT according to a second embodiment; and

FIG. 9 is a schematic plan view of another example TFT according to the second embodiment, different from that in FIG. 8.

### DESCRIPTION OF EMBODIMENTS

### First Embodiment

An embodiment of the present disclosure will be detailed. In the following description, unless otherwise specified, “A to B” indicating a numerical range means “not less than A and not more than B”.

### Configuration Of Photodetector

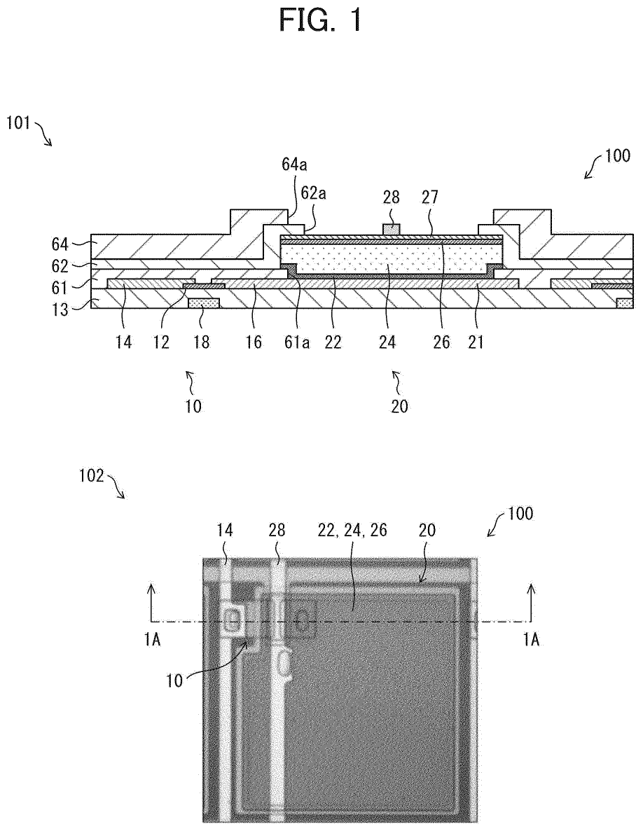

FIG. 1 is a schematic cross-sectional view and plan view of a photodetector 100 according to a first embodiment. In FIG. 1, Symbol 101 is the cross-sectional view, and Symbol 102 is the plan view. In particular, Symbol 101 is the cross-sectional view taken along line 1A-1A in Symbol 102.

The photodetector 100 is a flat-panel photodetector for instance, and is, for example, a photosensor, an image sensor, or a radiation detecting device (X-ray imaging display device), but is not limited thereto. As illustrated in FIG. 1, the photodetector 100 includes a thin-film transistor (TFT) 10 and a photodiode 20. The TFT 10 and the photodiode 20 are formed on a substrate not shown.

The TFT 10 detects an electric charge converted by the photodiode 20. To be specific, the TFT 10 is a switching element that undergoes switching in accordance with the electric charge converted by the photodiode 20. The TFT 10 includes an oxide semiconductor film 12, a source electrode 14, a drain electrode 16, and a gate electrode 18. The TFT 10 further includes a gate insulating film 13. The TFT 10 is a so-called bottom-gate TFT.

The oxide semiconductor film 12 may be an oxide semiconductor film containing at least one element selected from In, Ga, or Zn. This enables the photodetector 100 to have higher sensitivity and to be smaller than a photodetector including the oxide semiconductor film 12 formed from another oxide semiconductor. Nevertheless, the oxide semiconductor film 12 in the photodetector 100 may be an oxide semiconductor film containing none of In, Ga, and Zn.

The photodiode 20 converts light into an electric charge. The photodiode 20 includes a lower electrode 21 electrically connected to the drain electrode 16 of the TFT 10, an n-type semiconductor layer 22, an i-type semiconductor layer 24, a p-type semiconductor layer 26, and an upper electrode 27. In the example illustrated in FIG. 1, the lower electrode 21 is formed integrally with the drain electrode 16. However, the lower electrode 21 may be an electrode separate from the drain electrode 16 and connected to the drain electrode 16 by a wiring line or other things. The photodiode 20 further includes a wiring layer 28 for applying a bias. In view of visibility, the wiring layer 28 is spaced apart from the source electrode 14 in Symbol 101 as compared with Symbol 102.

The photodetector 100 further includes a first passivation film 61 covering the TFT 10. The first passivation film 61 includes a contact hole 61a for electrically connecting the lower electrode 21 and the n-type semiconductor layer 22 together.

The photodetector 100 further includes a second passivation film 62 covering the first passivation film 61 and a part of the photodiode 20. The second passivation film 62 includes an opening 62a for exposing the photodiode 20.

The photodetector 100 further includes a flattening film 64 covering the second passivation film 62. The photodetector 100 includes an opening 64a for exposing the photodiode 20.

The material, thickness, and other things of each constituent will be described together with an example method for manufacturing the photodetector 100 that will be described later on.

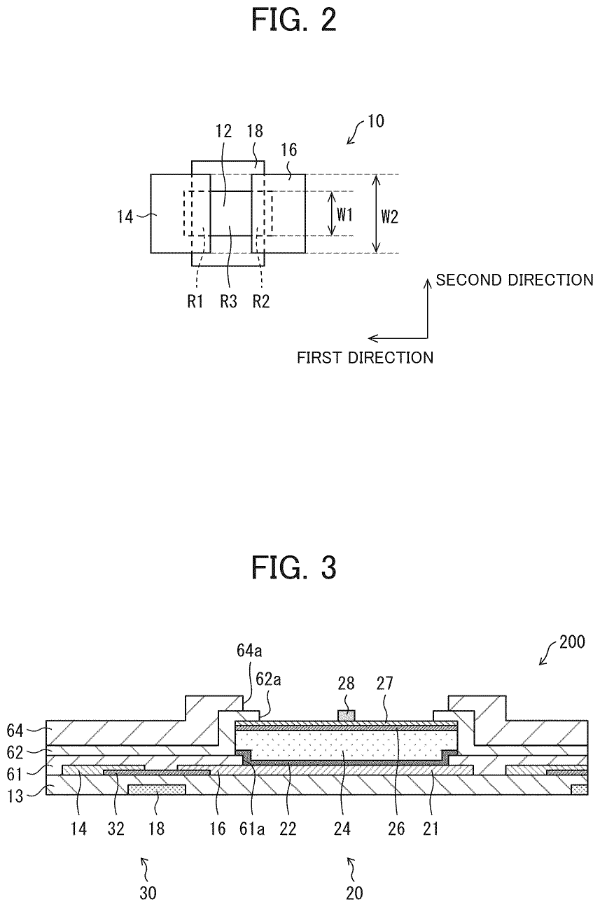

FIG. 2 is a schematic plan view of the TFT 10. FIG. 2 illustrates the oxide semiconductor film 12, source electrode 14, drain electrode 16, and gate electrode 18 of the TFT 10 in plan view of the oxide semiconductor film 12 with respect to the gate electrode 18 in a direction perpendicular to the oxide semiconductor film 12. FIG. 2 omits the gate insulating film 13.

As illustrated in FIG. 2, the oxide semiconductor film 12 includes a first region R1, a second region R2, and a third region R3 in the foregoing plan view. The first region R1 is a region where the oxide semiconductor film 12 overlaps the source electrode 14. The second region R2 is a region where the oxide semiconductor film 12 overlaps the drain electrode 16. The oxide semiconductor film 12 further overlaps the gate electrode 18 in both of the first region R1 and second region R2. The third region R3 is a region located between the first region R1 and the second region R2, and overlapping only the gate electrode 18.

In the foregoing plan view, a direction passing through the individual first region R1, second region R2, and third region R3 in the shortest distance will be referred to as a first direction. In addition, in the foregoing plan view, a direction perpendicular to the first direction will be referred to as a second direction. In other words, the second direction is a direction perpendicular to the first direction and perpendicular to the oxide semiconductor film 12. In FIG. 2, a width W1 is the width of the oxide semiconductor film 12 in the second direction. A width W2 is the widths of the source electrode 14 and drain electrode 16 in the second direction. It is noted that when the source electrode 14 and the drain electrode 16 have mutually different widths, the width W2 is the width of the source electrode 14 or the width of the drain electrode 16, whichever is smaller. In the TFT 10, the width W1 of the oxide semiconductor film 12 in the second direction is smaller than the width W2 of the source electrode 14 and drain electrode 16. For example, W1 is equal to 4 μm, and W2 is equal to 8 μm, but W1 and W2 are not limited to these measurements.

Comparison with Known Photodetector

FIG. 3 is a cross-sectional view of the schematic structure of a known photodetector 200. As illustrated in FIG. 3, the photodetector 200 includes a TFT 30 rather than the TFT 10. The TFT 30 includes an a-Si semiconductor film 32 rather than the oxide semiconductor film 12. The a-Si semiconductor film 32 is formed from amorphous silicon (a-silicon) rather than an oxide semiconductor.

Typically, oxide semiconductors have higher electric-charge mobility and smaller leakage current than a-Si. The photodetector 100 according to this embodiment, which includes the TFT 10 including the oxide semiconductor film 12 instead of the TFT 30 including the a-Si semiconductor film 32, improves sensitivity further than the photodetector 200.

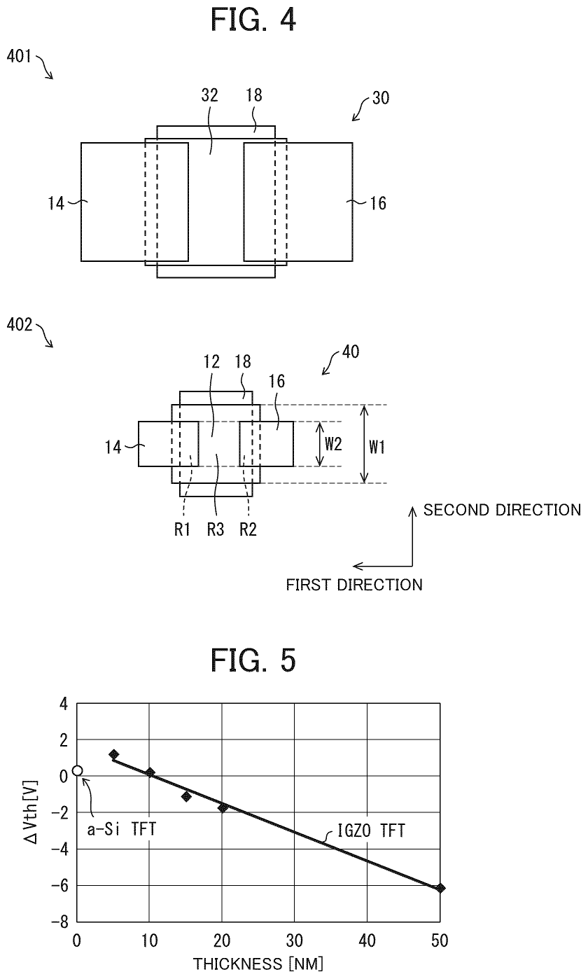

FIG. 4 is a plan view of the schematic structures of the TFT 30 and a TFT 40. The TFT 40 is a TFT according to a comparative example produced in the process of developing TFTs including the oxide semiconductor film 12. In FIG. 4, Symbol 401 shows the schematic structure of the TFT 30. Symbol 402 shows the schematic structure of the TFT 40. The TFT 40 includes the oxide semiconductor film 12, like the TFT 10. On the other hand, the TFT 40 is different from the TFT 10 in that the width W1 is larger than the width W2.

When the photodetector 100 is manufactured, the photodiode 20 is formed after the TFT 10 is formed. At this time, the TFT 10 sustains process damage, particularly damage due to dry etching, in the process of forming the photodiode 20. The degree of the damage depends on the size of the TFT 10, to be specific, the size of the oxide semiconductor film 12.

As illustrated in FIG. 4, the TFT 40 is formed smaller than the TFT 30. Further, the TFT 10 is similarly formed smaller than the TFT 30. Accordingly, the damage to the TFT 10 in the process of forming the photodiode 20 is reduced in the photodetector 100 when compared with a case where the TFT 10 is formed with the same size as the TFT 30.

FIG. 5 is a graph showing the relationship in the TFT 10 between the thickness of the gate insulating film 13 and the amount of variation, ΔVth, of a threshold voltage. In FIG. 5, the horizontal axis represents the thickness (nm) of the gate insulating film 13, and the vertical axis represents ΔVth (V). ΔVth denotes the amount of variation of the threshold voltage, Vth, in the TFT 10. The threshold voltage Vth is a gate voltage Vg when a drain current Id becomes a predetermined value. The predetermined value of the drain current Id is 1 nA for instance.

In the process of developing a TFT including the oxide semiconductor film 12, the inventors of the present application found out that the Vg-Id relationship and Vth were varied by X-ray irradiation of the TFT. To be specific, Vth is varied by X-ray irradiation of the TFT 10 including the oxide semiconductor film 12, and including the gate insulating film 13 at least a part of which is formed from silicon dioxide (SiO₂). As shown in FIG. 5, ΔVth denotes linear-functional change with a negative slope with respect to the thickness of SiO₂. Thus, SiO₂ thickness reduction in the gate insulating film 13 reduces ΔVth.

When the SiO₂ in the gate insulating film 13 is set to be about 10 nm thick, ΔVth in the TFT 10 is comparable to ΔVth in the TFT 30. However, the thickness of the gate insulating film 13 may vary.

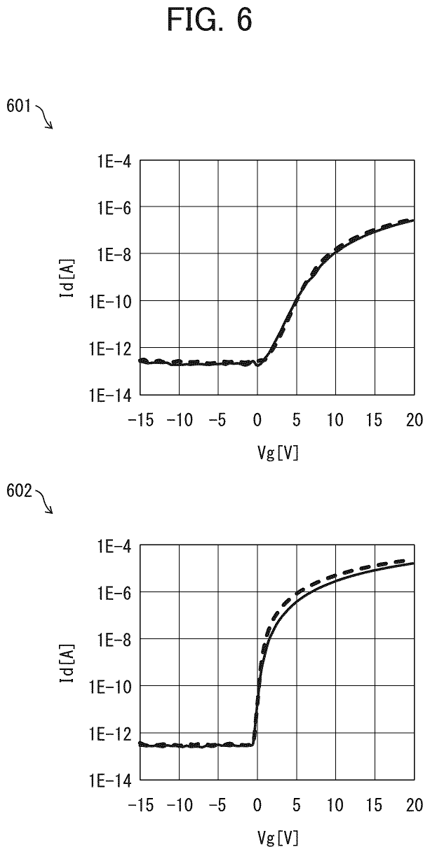

FIG. 6 is graphs showing the relationship between the gate voltage Vg and drain current Id in the TFTs 30 and 10. In FIG. 6, Symbol 601 shows the Vg-Id relationship in the TFT 30 in which W1 is set at 6 μm. In addition, Symbol 602 shows the Vg-Id relationship in the TFT 10 in which W1 is set at 6 μm and in which the SiO₂ thickness in the gate insulating film 13 is set at about 10 nm. In both Symbols 601 and 602, the horizontal axis represents Vg (V), and the vertical axis represents Id (A). Further, in both Symbols 601 and 602, the Vg-Id relationship before X-ray irradiation is denoted by a broken line, and the Vg-Id relationship after the X-ray irradiation is denoted by a solid line.

The TFT 30 in the example shown by Symbol 601 had a ΔVth of +0.3 V. On the other hand, the TFT 10 in the example shown by Symbol 602 had a ΔVth of +0.2 V, which was comparable to that in the example shown by Symbol 601. Further, the TFT 30 had a smaller drain current Id for turn-on than the TFT 10. This difference in Id for turn-on is a typical difference in characteristic between a TFT including an oxide semiconductor film and a TFT including an a-Si semiconductor film.

The size relationship between the width of the a-Si semiconductor film 32 and the widths of the source electrode 14 and drain electrode 16 was non-limiting in the TFT 30. Hence, some TFTs, like the TFT 40, in which W1 was larger than W2 were produced in the process of developing the TFT 10 including the oxide semiconductor film 12. The inventors of the present application found out that there was a difference in Vg-Id relationship change caused by X-ray irradiation between such a TFT as the TFT 40 in which W1 was larger than W2, and such a TFT as the TFT 10 in which W1 was smaller than W2.

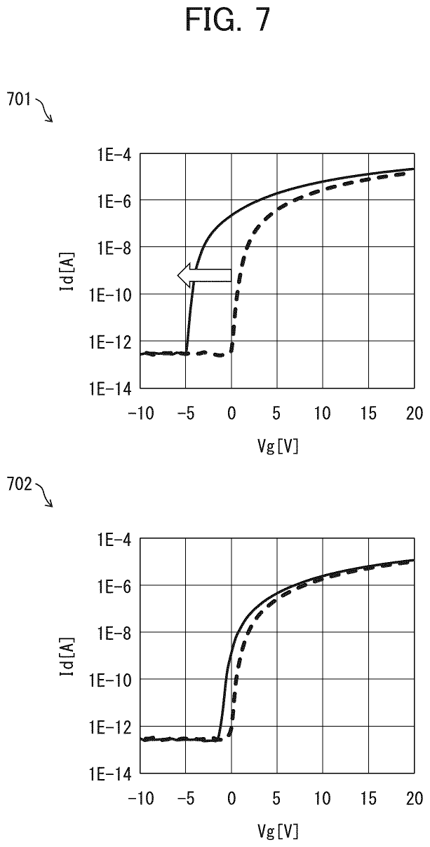

FIG. 7 is graphs showing example changes caused by X-ray irradiation, in the relationship between the gate voltage Vg and drain current Id in the TFTs 40 and 10. In FIG. 7, Symbol 701 is a graph showing an example Vg-Id relationship in the TFT 40 in which W1 is set at 8 μm and in which W2 is set at 4 μm. In addition, Symbol 702 is a graph showing an example Vg-Id relationship in the TFT 10 in which W1 is 4 μm and in which W2 is set at 8 μm. In both Symbols 701 and 702, the horizontal axis represents Vg (V), and the vertical axis represents Id (A). Further, in both Symbols 701 and 702, the graphs regarding the TFTs 40 and 10 before X-ray irradiation are denoted by broken lines, and the graphs regarding the TFTs 40 and 10 after the X-ray irradiation are denoted by solid lines.

Vg in the TFT 40 in the example shown by Symbol 701 had a threshold voltage Vth of +1.09 V before the X-ray irradiation, whereas Vg had a threshold voltage Vth of −3.89 V after the X-ray irradiation. On the other hand, Vg in the TFT 10 in the example shown by Symbol 702 had a threshold voltage Vth of +1.05 V before the X-ray irradiation, whereas Vg had a threshold voltage Vth of −0.06 V after the X-ray irradiation. That is, a case where W1 is smaller than W2 in the TFT including the oxide semiconductor film 12 exhibited a small Vth change caused by the X-ray irradiation, when compared with a case where W1 is larger than W2.

Irradiating the TFTs 10 and 40 with ionization radiations including X-rays generates electron-and-hole pairs within the gate insulating film 13. Among them, the electrons are emitted from the gate insulating film 13 in a short time. On the other hand, holes have smaller mobility than electrons. Thus, some of the holes within the gate insulating film 13 are trapped near the interface between the gate insulating film 13 and oxide semiconductor film 12, to turn into fixed positive electric charges. It is considered that the fixed positive electric charges within the gate insulating film 13 cause change in Vth.

The amount of trap of the fixed positive electric charges within the gate insulating film 13 is proportional to the 0.5th power to the second power of the SiO₂ thickness in the gate insulating film 13. Thus, ΔVth tends to rapidly become small along with SiO₂ thickness reduction. This is because that the SiO₂ thickness reduction causes holes injected into the oxide semiconductor film 12 to easily move through the gate insulating film 13 to the gate electrode 18 due to a tunnel effect, so that the electric-field intensity in the gate insulating film 13 is prevented from increase.

Further, a case where W1 is smaller than W2 exhibits a smaller area of the interface between the SiO₂ and oxide semiconductor film 12 than a case where W1 is larger than W2. As a result of this area reduction, the influence of the fixed positive electric charges within the gate insulating film 13 is reduced, thus reducing ΔVth.

The TFT 10 is formed such that W1 is smaller than W2, as earlier described. This provides smaller Vth change caused by X-ray irradiation than a case where a TFT is formed such that W1 is equal to or larger than W2.

### Manufacturing Method

The following describes a method for manufacturing the photodetector 100. The first process step is forming a 50- to 500-nm thick conductive film that is to be the gate electrode 18 onto a substrate.

Examples of the substrate include a glass substrate, a silicon substrate, and a heat-resistant plastic substrate. As the plastic substrate in particular, a polyethylene terephthalate (PET) substrate, a polyethylene naphthalate (PEN) substrate, a polyethersulfone (PES) substrate, an acrylic substrate, a polyimide substrate, or substrates of other materials can be used.

As the conductive film, a film of metal, such as aluminum (Al), tungsten (W), molybdenum (Mo), tantalum (Ta), chromium (Cr), titanium (Ti), or copper (Cu), of alloy thereof, or of metal nitride thereof can be appropriately used. Further, two or more of them may be stacked as the conductive film. For instance, a 370-nm thick film of W is formed onto the substrate, followed by a 50-nm thick film of TaN to form the gate electrode 18 having a stack of W and TaN (W/TaN=370 nm/50 nm). To be specific, W and TaN are evaporated onto the substrate through sputtering to form a film thereof, followed by photolithography through dry etching to form the gate electrode 18 having a desired shape.

The next is forming the gate insulating film 13 onto the gate electrode 18. The gate insulating film 13 may have a two-ply layer structure. As the gate insulating film 13, silicon oxide (SiOₓ), silicon nitride (SiNₓ), silicon oxynitride (SiOₓN_{y}, where x>y is established), silicon nitride oxide (SiNₓO_{y}, where x>y is established), or other materials can be used as appropriate. When the gate insulating film 13 has a two-ply layer structure, the lower gate insulating film located closer to the gate electrode 18 may be formed using, but not limited to, SiNₓ or SiNₓOy (where x>y is established) in order to avoid diffusion of impurities and other things from the substrate. In addition, the upper gate insulating film located opposite the gate electrode 18 may be formed using, but not limited to, SiOₓ or silicon oxynitride (SiOₓN_{y}, where x>y is established).

A dense insulating film can be formed at a relatively low temperature by mixing a rare gas, such as argon, into a reaction gas that is used for forming the gate insulating film 13, and by mixing the rare gas into the gate insulating film 13. Forming a dense insulating film as the gate insulating film 13 can reduce leakage current.

For instance, a 325-nm thick SiN film is deposited as a lower layer by using a chemical vapor deposition (CVD) apparatus. Furthermore, a 10-nm thick SiO₂ film is sequentially deposited as an upper layer thereonto to form the gate insulating film 13 having a two-ply layer structure.

The oxide semiconductor film 12 having a thickness of 30 to 100 nm is formed onto the gate insulating film 13. As earlier described, the oxide semiconductor film 12 may be an oxide semiconductor film containing at least one element selected from In, Ga, or Zn. To be specific, InGaO₃ (ZnO)₅, magnesium zinc oxide (MgₓZn₁₋ₓO), cadmium zinc oxide (CdₓZn₁₋ₓO), cadmium oxide (CdO), or an In—Ga—Zn—O amorphous oxide semiconductor (a-InGaZnO) can be used as the material of the oxide semiconductor film 12. Alternatively, ZnO to which one or more kinds of impurity elements from among group 1 elements, group 13 elements, group 14 elements, group 15 elements, group 17 elements, and others are added can be used as the material of the oxide semiconductor film 12. In this case, the ZnO may be amorphous ZnO, polycrystalline ZnO, or microcrystalline ZnO with a mixture of amorphous and polycrystalline ZnO. Furthermore, ZnO to which no impurity elements are added can be used as the material of the oxide semiconductor film 12.

For example, an oxide semiconductor film that is to be the oxide semiconductor film 12 is formed through sputtering. The next is photolithography using dry etching to form the oxide semiconductor film 12 having a desired shape.

The source electrode 14, the drain electrode 16, and the lower electrode 21, which is integrated with the drain electrode 16, are formed onto the oxide semiconductor film 12. To be specific, a conductive film is formed onto the gate insulating film 13 and oxide semiconductor film 12. Furthermore, the conductive film is processed into a desired shape through photolithography using a resist mask to form the source electrode 14, the drain electrode 16, and the lower electrode 21. As the conductive film, metal, such as aluminum (Al), tungsten (W), molybdenum (Mo), tantalum (Ta), copper (Cu), chromium (Cr), or titanium (Ti), alloy thereof, or metal nitride thereof can be appropriately used. Here, a Ti film, an Al film, and a Ti film respectively having thicknesses of 100 nm, 300 nm, and 30 nm are formed through sputtering, followed by photolithography using dry etching to form the source electrode 14, drain electrode 16, and lower electrode 21 each having a desired shape. Through the foregoing process steps, the TFT 10 is formed. In addition, the lower electrode 21 of the photodiode 20 is also formed.

The first passivation film 61 is formed with a thickness of 200 to 300 nm so as to cover the TFT 10 and the lower electrode 21. The first passivation film 61 may be formed by using a thin-film formation method, such as plasma CVD or sputtering. The first passivation film 61 can be made of insulating material, such as silicon nitride, silicon oxide, silicon nitride oxide, or silicon oxynitride. Further, the first passivation film 61 is not limited to a monolayer; it may include two layers, or three or more layers. A resist mask is formed onto the first passivation film 61, followed by photolithography using dry etching to form the contact hole 61a such that the lower electrode 21 is exposed from the first passivation film 61. Further, the entire substrate may further undergo heating after the first passivation film 61 is formed. The heating is performed until, for instance, the substrate reaches 350° C.

The n-type semiconductor layer 22, the i-type semiconductor layer 24, and the p-type semiconductor layer 26 are formed onto the lower electrode 21 in the stated order through, for instance, CVD. The n-type semiconductor layer 22 is formed from amorphous silicon (a-Si) for instance, and forms an n+region. The n-type semiconductor layer 22 has a thickness of about 10 to 50 nm for instance. The i-type semiconductor layer 24 is a semiconductor layer having lower conductivity than the n-type semiconductor layer 22 and p-type semiconductor layer 26; for instance, the i-type semiconductor layer 24 is a non-doped intrinsic semiconductor layer, and is formed from amorphous silicon (a-Si) for instance. The i-type semiconductor layer 24 has a thickness of about 400 to 1000 nm for instance. The optical sensitivity of the photodiode 20 can be enhanced as the thickness of the i-type semiconductor layer 24 increases. The p-type semiconductor layer 26 is formed from amorphous silicon (a-Si) for instance, and forms a p+region. The p-type semiconductor layer 26 has a thickness of about 40 to 50 nm for instance. It is noted that the p-type semiconductor layer 26 may be formed by implanting B into the upper layer of the i-type semiconductor layer 24 through ion shower doping or ion implantation.

The upper electrode 27 is formed onto the p-type semiconductor layer 26. The upper electrode 27 is formed from indium zinc oxide (IZO) or indium tin oxide (ITO) for instance. The upper electrode 27 is formed in the upper region of the p-type semiconductor layer 26 through sputtering and photolithography.

The second passivation film 62 is next formed. The second passivation film 62 covers the entire first passivation film 61, the side surface of the photodiode 20, and a part of the upper electrode 27 of the photodiode 20. The second passivation film 62 is formed from, for instance, the same material as that of the first passivation film 61. To be specific, a film of insulating material is formed through, for instance, CVD so as to cover the first passivation film 61 and the photodiode 20. Then, the opening 62a is provided in a part of the upper surface of the photodiode 20 through photolithography, thus forming the second passivation film 62.

The flattening film 64 is formed onto the second passivation film 64. The flattening film 64 is formed from inorganic insulating material or organic insulating material. Examples of the inorganic insulating material include silicon dioxide, silicon nitride, silicon oxynitride, silicon nitride oxide, and tetraethyl orthosilicate (TEOS). To be specific, a film of inorganic insulating material or organic insulating material is formed onto the entire second passivation film 62 through CVD or other other methods. Then, the opening 64a is provided in a part of the upper surface of the photodiode 20 through photolithography, thus forming the flattening film 64.

The wiring layer 28 is formed, through sputtering or photolithography for instance, onto the upper electrode 27 of the photodiode 20 exposed from the opening 64a of the flattening film 64. The wiring layer 28 is formed from, but not limited to, Mo or Ti.

The photodetector 100 can be manufactured through the foregoing process steps. Furthermore, a wavelength conversion layer (not shown), such as a scintillator, that converts radiations into light is formed onto the upper side of the photodiode 20, and thus, a radiographic imaging device including the photodetector 100 can be manufactured. The scintillator is formed from, for example, cesium iodide (CsI) or gadolinium oxysulfide (Gd₂O₂S).

### Second Embodiment

Another embodiment of the present disclosure will be described. It is noted that for convenience in description, components having the same functions as those of the components described in the foregoing embodiment will be denoted by the same signs, and that their descriptions will not be repeated.

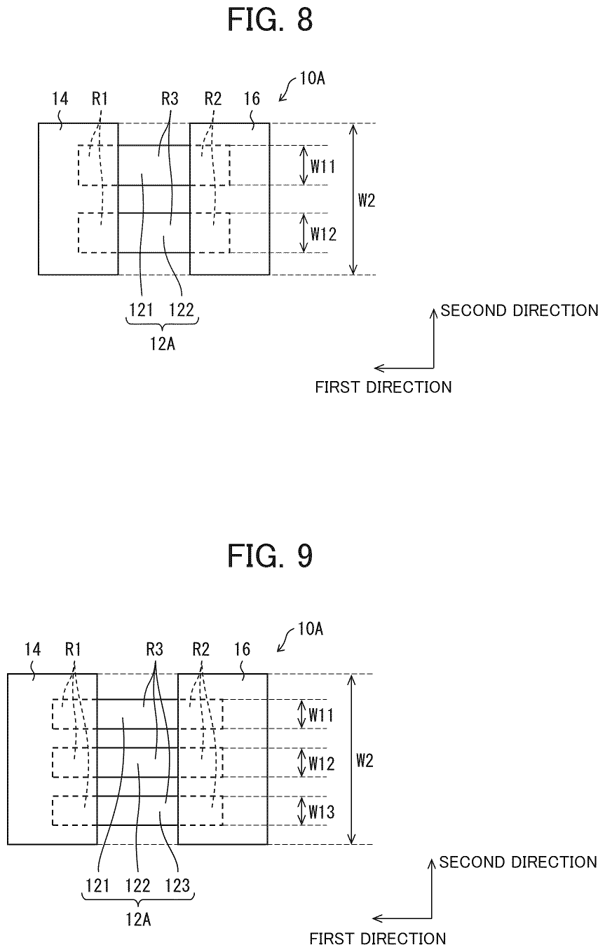

FIG. 8 is a schematic plan view of an example TFT 10A according to a second embodiment. FIG. 9 is a schematic plan view of another example of the TFT 10A different from that in FIG. 8. FIGS. 8 and 9 omit the gate electrode 18. The TFT 10A is different from the TFT 10 in that the TFT 10A includes an oxide semiconductor film 12A instead of the oxide semiconductor film 12.

In the example illustrated in FIG. 8, the oxide semiconductor film 12A includes a first portion 121 and a second portion 122. The first portion 121 and the second portion 122 are arranged in parallel with each other in the second direction. In other words, the oxide semiconductor film 12A is divided into two parts: the first portion 121 and the second portion 122, along the second direction.

In FIG. 8, a width W11 is the width of the first portion 121 in the second direction. In addition, a width W12 is the width of the second portion 122 in the second direction. In the TFT 10A, the sum of the widths W11 and W12 in the oxide semiconductor film 12A is smaller than the width W2.

Further, like the example illustrated in FIG. 9, the oxide semiconductor film 12A may further include a third portion 123 in addition to the first portion 121 and the second portion 122. In this example, the first portion 121, the second portion 122, and the third portion 123 are arranged in parallel with each other in the second direction. In other words, the oxide semiconductor film 12A is divided into three parts: the first portion 121, the second portion 122, and the third portion 123, along the second direction.

In FIG. 9, a width W13 is the width of the third portion 123 in the second direction. In the example illustrated in FIG. 9, the sum of the widths W11, W12, and W13 in the oxide semiconductor film 12A is smaller than the width W2.

Furthermore, the oxide semiconductor film 12A may be divided into four or more portions along the second direction. In this case as well, the sum of the widths of the plurality of divided oxide semiconductor films 12A in the second direction is preferably smaller than the width W2 of the source electrode 14 and drain electrode 16. This enables the photodetector 100 including the TFT 10A to reduce Vth change caused by X-ray irradiation, like that including the TFT 10.

Furthermore, the oxide semiconductor film 12A in the TFT 10A is divided into a plurality of portions; consequently, even if the conductivity of any of the plurality of divided oxide semiconductor films 12A deteriorates, current can flow through the other oxide semiconductor films 12A. This can reduce the influence of such a conductivity deterioration.

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

While there have been described what are at present considered to be certain embodiments of the disclosure, it will be understood that various modifications may be made thereto, and it is intended that the appended claim cover all such modifications as fall within the true spirit and scope of the disclosure.

What is claimed is:

1. A photodetector comprising:
a photodiode configured to convert light into an electric charge; and
a thin-film transistor (TFT) configured to detect the electric charge,
wherein the TFT includes
a gate electrode,
a source electrode,
a drain electrode, and
an oxide semiconductor film striding between the source electrode and the drain electrode,
wherein the oxide semiconductor film includes
a first region overlapping the source electrode in a plan view,
a second region overlapping the drain electrode in the plan view, and
a third region located between the first region and the second region, and overlapping only the gate electrode in the plan view, and
wherein in the plan view, a width of the oxide semiconductor film in a second direction is smaller than widths of the source and drain electrodes, the second direction being perpendicular to a first direction and perpendicular to the oxide semiconductor film, the first direction being a direction passing through the individual first, second, and third regions in a shortest distance.

2. The photodetector according to claim 1, wherein
the oxide semiconductor film is divided into a plurality of oxide semiconductor films in the second direction, and
a sum of the widths of the plurality of divided oxide semiconductor films in the second direction is smaller than the widths of the source and drain electrodes in the second direction.

3. The photodetector according to claim 1, wherein the oxide semiconductor film is an oxide semiconductor film containing at least one element selected from In, Ga, or Zn.
